(19) United States
(12) Patent Application Publication
(10) Pub. No.: US 2026/0020340 A1
(43) Pub. Date: Jan. 15, 2026

(54) STACKED FETS WITH INTERDEVICE POWER DELIVERY

(71) Applicant: INTERNATIONAL BUSINESS MACHINES CORPORATION, Armonk, NY (US)

(72) Inventors: Shay Reboh, Guilderland, NY (US); Chen Zhang, Santa Clara, CA (US); Nicholas Anthony Lanzillo, Wynantskill, NY (US); Ruilong Xie, Niskayuna, NY (US)

(21) Appl. No.: 18/771,589

(22) Filed: Jul. 12, 2024

(51) Int. Cl. H01L 27/118

(52) U.S. Cl. CPC H10D 84/907; H10D 84/953; H10D 84/981

(57) ABSTRACT

A semiconductor device includes a stacked transistor structure having field effect transistors on two vertically stacked levels. An interdevice region is disposed between the two vertically stacked levels. A first power line is disposed within the interdevice region, and a second power line is disposed within the interdevice region and vertically spaced from the first power line.

### BACKGROUND

The present invention relates generally to semiconductor devices and methods for fabrication, and more particularly to stacked field effect transistor devices (FETs) having interdevice power delivery to enable cell height scaling.

Semiconductor devices are used in a variety of electronic applications, such as personal computers, cell phones, digital cameras, and other electronic equipment. Semiconductor devices are usually fabricated by sequentially depositing insulating or dielectric layers, conductive layers, and semiconductive layers of material over a semiconductor substrate and patterning the various material layers using lithography to form circuit components and elements thereon.

The semiconductor industry has experienced rapid growth due to improvements in the integration density of a variety of electronic components (e.g., transistors, diodes, resistors, capacitors, etc.). For the most part, this improvement in integration density has come from shrinking the semiconductor process node. With the increased demands for miniaturization, higher speed, greater bandwidth, lower power consumption, and lower latency, chip layout has become more complicated and difficult to achieve in the production of semiconductor dies.

Stacked transistor devices may be used to increase areal density of devices on a chip. Additionally, the close proximity of the overlying and underlying devices can be useful when forming paired devices, such as complementary semiconductor devices that include two devices of opposing polarity. However, positioning transistors above one another places spatial and electrical constraints that can make it challenging to provide required performance. Cell height scaling has become elusive as pitch is approaching its physical limits.

Therefore, a need exists for stacked transistor devices that can scale with shrinking node sizes. A further need exists for stacked transistor devices that enable a reduction in cell height for the stacked transistor devices.

### SUMMARY

In accordance with an embodiment of the present invention, a semiconductor device includes a stacked transistor structure having field effect transistors on two vertically stacked levels. An interdevice region is disposed between the two vertically stacked levels. A first power line is disposed within the interdevice region.

In other embodiments, the first power line can connect to a source/drain electrode of a field effect transistor by a line-of-sight contact. The first power line can connect to source/drain electrodes on the two vertically stacked levels. The first power line can be encapsulated by dielectric material. The dielectric material can separate a gate into corresponding gate conductors for the two vertically stacked levels. The semiconductor device can further include a second power line disposed within the interdevice region. The second power line can be vertically aligned with the first power line. The second power line can be vertically misaligned from the first power line.

In accordance with another embodiment of the present invention, a semiconductor device includes a stacked transistor structure having field effect transistors on two vertically stacked levels. An interdevice region is disposed between the two vertically stacked levels. A first power line is disposed within the interdevice region, and a second power line is disposed within the interdevice region and vertically spaced from the first power line.

In other embodiments, the first power line can connect to a source/drain electrode of a field effect transistor by a line-of-sight contact. The first power line can connect to source/drain electrodes on the two vertically stacked levels. The first power line can be encapsulated by dielectric material and the dielectric material can separate a gate into corresponding gate conductors for the two vertically stacked levels. The second power line can be vertically aligned with the first power line. The second power line can be vertically misaligned from the first power line. The first power line can connect to a field effect transistor on a first level and the second power line connects to a field effect transistor on a second level. The first power line can include a positive supply voltage (VDD) and the second power line includes a negative supply voltage (VSS).

In accordance with another embodiment of the present invention, a semiconductor device, includes a stacked transistor structure having field effect transistors on two vertically stacked levels and disposed within a three track pitch width. An interdevice region is disposed between the two vertically stacked levels within the three track pitch width. A first power line is disposed within the interdevice region.

In other embodiments, the first power line can connect to a source/drain electrode of a field effect transistor by a line-of-sight contact. The first power line can connect to source/drain electrodes on the two vertically stacked levels. The first power line can be encapsulated by dielectric material, and the dielectric material can separate a gate conductor between the two vertically stacked levels. The semiconductor device can further include a second power line disposed within the interdevice region, wherein the second power line is vertically aligned with the first power line. The semiconductor device can further include a second power line disposed within the interdevice region, wherein the second power line is vertically misaligned from the first power line. The stacked transistor structure can include six signal lines within the three track pitch width. The stacked transistor structure can be disposed within a two track pitch width. The stacked transistor structure can include four signal lines within the two track pitch width.

In accordance with another embodiment of the present invention, a semiconductor device, includes a stacked transistor structure having field effect transistors on two vertically stacked levels and disposed within a three track pitch width. An interdevice region is disposed between the two vertically stacked levels within the three track pitch width. A first power line is disposed within the interdevice region. A second power line is disposed within the interdevice region and vertically spaced from the first power line. A dielectric material in the interdevice region encapsulates the first power line and the second power line.

In other embodiments, the interdevice region can separate a gate conductor between the two vertically stacked levels. The stacked transistor structure can be disposed within a two track pitch width.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a layout view showing section lines labeled Source, Drain and Gate where cross-sections are taken of a semiconductor device depicted in cross-sectional views of FIGS. 2-8, in accordance with an embodiment of the present invention;

FIG. 2 shows cross-sectional views, taken at section lines labeled Source, Drain and Gate in FIG. 1, depicting a source cell, a drain cell and a gate cell within three track pitch widths and having an interdevice region with two power lines and three signal lines per cell, in accordance with an embodiment of the present invention;

FIG. 3 shows cross-sectional views, taken at section lines labeled Source, Drain and Gate in FIG. 1, depicting a source cell, a drain cell and a gate cell within three track pitch widths and having an interdevice region with two power lines and six signal lines per cell, in accordance with an embodiment of the present invention;

FIG. 4 shows a cross-sectional view, taken at section line labeled Gate in FIG. 1, depicting a gate cell within three track pitch widths and having an interdevice region with two power lines separating a gate structure into two gate conductors associated with a top and bottom field effect transistor (each field effect transistor corresponding to a vertically stacked device level), in accordance with an embodiment of the present invention;

FIG. 5 shows cross-sectional views, taken at section lines labeled Source, Drain and Gate in FIG. 1, depicting a source cell, a drain cell and a gate cell within two track pitch widths and having an interdevice region with two power lines and four signal lines per cell, in accordance with an embodiment of the present invention;

FIG. 6 shows a cross-sectional view, taken at section line labeled Gate in FIG. 1, depicting a gate cell within two track pitch widths and having an interdevice region with two power lines separating a gate structure into two gate conductors associated with a top and bottom field effect transistor (each field effect transistor corresponding to a vertically stacked device level), in accordance with an embodiment of the present invention;

FIG. 7 shows a cross-sectional view, taken at section line labeled Source in FIG. 1, depicting a source cell within two track pitch widths and having an interdevice region with two power lines connected to adjacent source electrodes (above and below) by line-of-sight contacts, in accordance with an embodiment of the present invention; and

FIG. 8 shows a cross-sectional view, taken at section line labeled Source in FIG. 1, depicting a source cell within two track pitch widths and having an interdevice region with two vertically misaligned or offset power lines connected to adjacent source electrodes (above and below) by line-of-sight contacts, in accordance with an embodiment of the present invention.

### DETAILED DESCRIPTION

In accordance with embodiments of the present invention, devices and methods are described which include stacked field effect transistor (FET) devices having interdevice power delivery. The interdevice power delivery can include a power rail or power rails disposed between top and bottom FETs, which can partially be embodied by semiconductor materials grown epitaxially from a channel material (epitaxial regions or epi regions can also be collectively referred to as source/drain regions or electrodes) in a FET stack. By moving power rails to a more central position, a density of signal lines (contacts, metal lines, etc.) above and below the stacked FETs can be altered, and space can be better utilized to permit for a reduction in cell height. Said differently; by removing the power rails from a frontside and/or backside of a device, space can be created for more signal lines or to scale down cell height. A density of signal lines can be increased or decreased to permit higher reliability (less opens or shorts) and better apportion space. The power rails will be referred to as power lines and metal lines interchangeably.

Cell height scaling has become increasingly more difficult and device pitches approach physical limits. Cell scaling can be improved by leveraging a semiconductor conductor device thickness to reduce layout area. While power lines can be moved, e.g., from a frontside of a semiconductor to employ a backside power distribution network (BSPDN), limitations exist. For example, distances for connections from a frontside to a backside can be increased, and vias from the frontside to the backside need to pass through or in between front end of the line devices. This can cause increased short-circuit concerns due to congestion at the device level and also open-circuit concerns due to high-aspect ratio metal fill processes, which are difficult.

The power lines can be locally formed, as needed or in accordance with a semiconductor device design. For example, the power lines, while they can be part of a power plane, can be locally formed in a specific region or cell and not part of a power plane that extends across the device or across a large region of the device. Said differently, the power lines can be formed in a specific region (locally) where signal line density is an issue and not in other regions where signal line density is not an issue.

In an embodiment, sequential integration of stacked field effect transistors (FETs) can extend scaling by introducing power delivery lines in an interdevice region. The interdevice region is located between layers of stacked FETs in a vertical position. Said differently, the power lines will have source/drain regions for FETs above and below the power lines in a vertical column. By disposing the power lines in an intermediate vertical position, the frontside and the backside of the device can employ the available space for signal routing to permit scaling of stacked FETs.

In some embodiments, stacked FETs can have a power line disposed in between a top and bottom FET. Horizontal metal lines can be disposed in between layers of epi regions. In an embodiment, a plurality of metal lines can be stacked in the interdevice region. In a particularly useful embodiment, two metal lines can be stacked in the interdevice region. The power lines are separated vertically by a dielectric material. The power lines can be vertically aligned or offset (misaligned) relative to one another. The power lines can be at least partially superimposed (e.g., overlap in the vertical direction). In other embodiments, more than two power lines can be stacked in the interdevice region.

The power lines located in the interdevice region provide an inter-FET or intermediate power distribution network (IPDN). IPDN can include larger power lines due to relaxed pitch conditions. For example, in a split gate embodiment where a gate is split into two portions vertically disposed relative to one another, the power lines can extend across an entire width of a gate structure (e.g., from gate cut to gate cut). This increases the width and therefore the size of the power lines. The power lines can be made thicker to take advantage of the availability of space in a height or vertical dimension. In one example, the power lines can include a thickness that can be up to or exceed 16 nm. Larger power lines have lower electrical resistance, which reduces voltage drop and improves overall chip performance.

In some embodiments, backside processing can be performed to fabricate a BSPDN. However, in other embodiments, backside processing can be avoided using power lines in the interdevice region. By employing the IPDN in accordance with embodiments of the present invention, all integration or fabrication of the semiconductor device can be performed from the frontside. This can avoid backside processing which can lead to overlay issues, e.g., a BSPDN includes layers of vias and metal lines that need to be aligned in order to make contact and to avoid open circuits. In addition, distances for connections from the frontside and to front end or line devices is reduced.

Consideration regarding materials selection includes selecting a conductive material consistent with frontside processing. For example, the power lines are fabricated prior to the fabrication of top epi regions. As such, fabrication temperatures could impact material selection of the power lines. For example, W or Ru may be preferred over Cu if fabrication temperatures exceed, e.g., 500 ºC.

The power lines within the interdevice region can benefit from a shielding effect of surrounding components. For example, in structures where crosstalk between components is an issue, by locating power lines within the interdevice region, crosstalk can be reduced between selected components. In other embodiments, locating the power lines in the interdevice region can provide a location that can be employed to optimize capacitance concerns.

The power lines within the interdevice region permits immediate and direct access (e.g., line-of-sight contacts) to source/drain electrodes. In one example, a top power line can connect by a via to a source of a top FET. In another example, a bottom power line can connect by a via to a source of a bottom FET. In another example, the top power line can connect to the source of a top FET, and the bottom power line can connect the source of a bottom FET. Similar connections can be made to a drain of a top or bottom FET.

With the use of power lines located in the interdevice region in accordance with embodiments of the present invention, stacked FETs can have a cell height within a length (height) defined by three metal line pitches (three metal lines and three spaces between metal lines). In an embodiment, the three metal lines are inbound in the cell, but the cell can be larger than the three metal tracks. In other embodiments, stacked FETs can have a cell height within a length (height) defined by two metal line pitches (two metal lines and two spaces between metal lines). The two metal lines are inbound in the cell, but the cell can be larger than the two metal tracks.

Stacked FETs can be formed with two signal metal tracks on the frontside, two metal tracks on the backside (e.g., four metal tracks) and one or more power lines in the interdevice region. In other embodiments, stacked FETs can be formed with three signal metal tracks on the frontside, three metal tracks on the backside (e.g., six metal tracks) and one or more power lines in the interdevice region. Combinations of different numbers of tracks are also contemplated, e.g., two tracks on the frontside and three of the backside, etc.

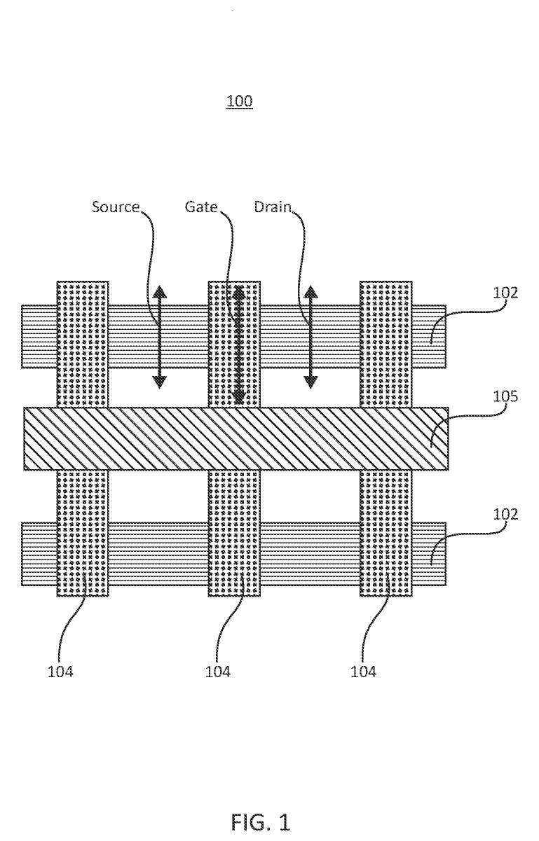

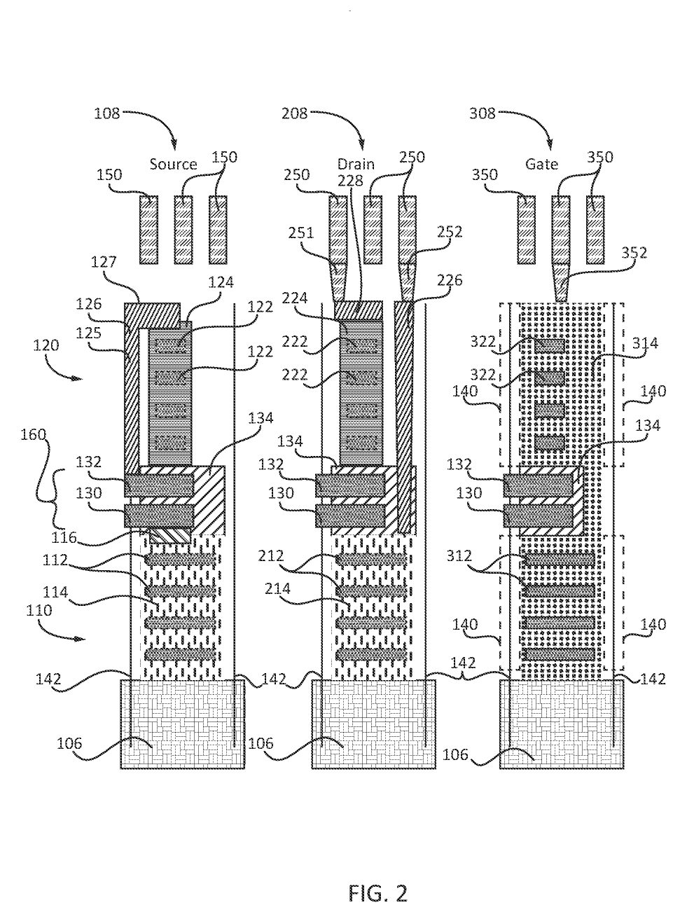

Referring now to the drawings in which like numerals represent the same or similar elements and initially to FIG. 1, devices and methods for manufacturing a stacked field effect transistor (FET) device are shown in accordance with embodiments of the present invention. A layout view of a semiconductor device 100 is shown. The layout view shows active region lines 102 and gate lines 104. A gate cut 105 is also shown. Section lines for a “Source”, a “Gate” and a “Drain” are indicated and shown cross-sectional cuts for corresponding sections labeled “Source”, “Gate” and “Drain” throughout FIGS. 2-4. Active region lines 102 represent stacked source/drain (S/D) regions for transistor devices, and gate lines 104 are represent gate structures for such transistor devices. Transistor channels are formed along the active region lines 102 below the gate lines 104.

It should be understood that channel positions 112, 122, 212, 222, 712, 722, 812, 822 depicted in the Source and Drain cross-sectional views throughout the FIGs. are for reference to depict channel positions relative to the respective source or drain regions. The channels are not physically present within the respective source/drain regions. However, the channels depicted in the Gate cross-sectional views are physically present.

Referring to FIG. 2, cross-sectional views of cells 108, 208 and 308 are shown in accordance with an embodiment. Cell 108 is a stacked FET cell showing for a source section (Source) taken at section line Source in FIG. 1. Cell 108 includes a bottom source electrode 114 for a bottom FET 110 and a top source electrode 124 for a top FET 120. Cell 108 occupies three tracks (pitches) and includes three signal lines 150 at a frontside of the cell 108. The bottom source electrode 114 and the top source electrode 124 illustratively show channel positions 112 and 122, respectively therein, which are not physically present within the bottom source electrode 114 and the top source electrode 124. The cell 108 includes a boundary 142 that can include a cut region 140, which includes a dielectric material to laterally isolate components within the cell 108. The dielectric material can include a gate cut dielectric or an interlayer dielectric, as appropriate. The cut regions 140 can be a gate cut only or can extend in between gates as well.

Channel positions 122 and 112 are associated with structures provided by nanosheets during fabrication of the top source electrode 124 and the bottom source electrode 114 and include semiconductor material from which the bottom source electrode 114 and the top source electrode 124 can be grown using, e.g., an epitaxial growth process. The semiconductor material used for channels 312, 322 can include, e.g., a silicon-containing material. Illustrative examples of Si-containing materials can include, but are not limited to Si, SiGe, SiGeC, SiC and multi-layers thereof. In particularly useful embodiments, channels 312, 322 can include Si or SiGe, where Ge is between about 30 atomic % and 55 atomic % of the compound. It should be understood that other materials or atomic percentages can also be employed.

In cell 108, the top source electrode 124 includes an associated channel width (channel position 122) that is smaller than an associated channel width (channel position 112) of the bottom source electrode 114. Correspondingly, channels associated with channel positions 112 are larger than channels associated with channel positions 122.

The stacked FETs can be formed on or over a substrate, which can be removed and replaced with a dielectric material 106 during fabrication. In other embodiments, the substrate can remain in the position of the dielectric material 106 with adequate isolation from the bottom source electrode 114.

Formation of the bottom source electrode 114 and the top source electrode 124 can include employing an epitaxial growth process. The bottom source electrode 114 and the top source electrode 124 form source regions for the bottom FET 110 and the top FET 120, respectively in a stacked FET device. The bottom source electrode 114 and the top source electrode 124 can include Si or SiGe. In an embodiment, the bottom source electrode 114 and the top source electrode 124 can be designated as P-type or N-type devices. For example, if the bottom source electrode 114 and the top source electrode 124 include N-type devices than Si can be employed. In another example, if the bottom source electrode 114 and the top source electrode 124 include P-type devices than the bottom source electrode 114 and the top source electrode 124 can include SiGe.

The bottom source electrode 114 and the top source electrode 124 can be appropriately doped during their formation by epitaxial growth. For example, the bottom source electrode 114 and the top source electrode 124 can be doped by introducing p dopants (e.g., B, Ga, etc.) during epitaxial formation. Similarly, the bottom source electrode 114 and the top source electrode 124 can be doped by introducing n dopants (e.g., P, As, etc.) during epitaxial formation. In other embodiments, P-type and N-type devices can be formed over one another. For example, the bottom source electrode 114 can have a first conductivity and the top source electrode 124 can have a different conductivity.

The bottom source electrode 114 and the top source electrode 124 are vertically separated or spaced by an interdevice region 160. The interdevice region 160 can include a dielectric material 134, which is built up in layers during fabrication to permit one or more metal lines 130, 132 (power lines) to be formed therein. In the embodiment shown, two stacked metal lines 130 and 132 are shown disposed within the interdevice region 160. However, one, two, three or more metal lines can be employed. The metal lines 130 and 132 are shown vertically aligned to one another. In other embodiments, the metal lines 130 and 132 can be vertically offset or misaligned from one another to provide access areas for contacts or vias to land from a frontside or backside of the cell 108. The power lines or metal lines 130 and 132 can include a positive supply voltage (VDD) and a negative supply voltage (VSS) (or vice versa).

The metal lines 130 and 132 can be connected to the top source electrode 124 and/or the bottom source electrode 114. In the embodiment shown in FIG. 2, the top source electrode 124 is connected to the metal line 130 by an L-shaped connector 126. The L-shaped connector 126 includes a contact portion 127 and a via portion 125. The contact portion 127 connects to a frontside of the top source electrode 124 while the via portion 125 lands on the metal line 132. The L-shaped connector 126 forms an indirect contact since it connects a top portion of the top source electrode to the metal line 132 on an opposite end of the top source electrode 124. The bottom source electrode 114 connects to the metal line 130 by a contact 116. Contact 116 is a line-of-sight contact as it provides a direct connection between the metal line 130 and the bottom source electrode 114.

It should be understood that a number of connection options exist for connecting the metal lines 130 and 132 to the top source electrode 124 and/or the bottom source electrode 114. These can include indirect and/or line of sight connections to one or both of the metal lines 130 and 132 to each of or both of the top source electrode 124 and/or the bottom source electrode 114. Any combination of connections can be realized in accordance with a desired wiring scheme.

Cell 208 is a stacked FET cell showing a drain section (Drain) taken at section line Drain in FIG. 1. Cell 208 includes a bottom drain electrode 214 for the bottom FET 110 and a top drain electrode 224 for the top FET 120. Cell 208 occupies three tracks (pitches) and includes three inbound signal lines 250 at the frontside of the cell 208. One signal line 250 connects to a via 251 that connects to a contact 228 of the top drain electrode 224. Another signal line 250 connects to a via 252 that connects to a contact 226 of the bottom drain electrode 214. The contact 226 passes through the dielectric material 134. The cell 208 includes a boundary 142 that can include a dielectric material to laterally isolate components within the cell 208. The dielectric material can include a gate cut dielectric or an interlayer dielectric, as appropriate.

Channel positions 222 and 212 are associated with structures provided by nanosheets during fabrication of the top drain electrode 224 and the bottom drain electrode 214 and include semiconductor material from which the bottom drain electrode 214 and the top drain electrode 224 can be grown using, e.g., an epitaxial growth process.

In cell 208, the top drain electrode 224 includes an associated channel width (channel position 222) that is smaller than an associated channel width (channel position 212) of the bottom drain electrode 214. Correspondingly, channels associated with channel positions 212 are larger than channels associated with channel positions 222.

The stacked FETs can be formed on or over a substrate, which can be removed and replaced with the dielectric material 106 during fabrication. In other embodiments, the substrate can remain in the position of the dielectric material 106 with adequate isolation from the bottom drain electrode 214.

Formation of the bottom drain electrode 214 and the top drain electrode 224 can include employing an epitaxial growth process. The bottom drain electrode 214 and the top drain electrode 224 form drain regions for the bottom FET 110 and the top FET 120, respectively in a stacked FET device. The bottom drain electrode 214 and the top drain electrode 224 can include Si or SiGe. In an embodiment, the bottom drain electrode 214 and the top drain electrode 224 can be designated as P-type or N-type devices. For example, if the bottom drain electrode 214 and the top drain electrode 224 include N-type devices than Si can be employed. In another example, if the bottom drain electrode 214 and the top drain electrode 224 include P-type devices than the bottom drain electrode 214 and the top drain electrode 224 can include SiGe.

The bottom drain electrode 214 and the top drain electrode 224 can be appropriately doped during their formation by epitaxial growth. For example, the bottom drain electrode 214 and the top drain electrode 224 can be doped by introducing p dopants (e.g., B, Ga, etc.) during epitaxial formation. Similarly, the bottom drain electrode 214 and the top drain electrode 224 can be doped by introducing n dopants (e.g., P, As, etc.) during epitaxial formation. In other embodiments, P-type and N-type devices can be formed over one another. For example, the bottom drain electrode 214 can have a first conductivity and the top drain electrode 224 can have a different conductivity.

The bottom drain electrode 214 and the top drain electrode 224 are vertically separated by the interdevice region 160. The interdevice region 160 can include a dielectric material 134, which is built up in layers during fabrication to permit one or more metal lines 130, 132 (power lines) to be formed therein. In the embodiment shown, two stacked metal lines 130 and 132 are shown disposed within the interdevice region 160. However, one, two, three or more metal lines can be employed. The metal lines 130 and 132 are shown vertically aligned to one another. In other embodiments, the metal lines 130 and 132 can be vertically offset from one another to provide access areas for contacts or vias to land from the frontside or backside of the cell 208.

The metal lines 130 and 132 can be connected to the top drain electrode 224 and/or the bottom drain electrode 214. In the embodiment shown in FIG. 2, the top drain electrode 224 is not connected to the metal line 130 and the bottom drain electrode 214 is not connected to the metal line 132. Instead, the metal lines pass through the interdevice region 160. In other embodiments, contact can be made to the metal lines 130, 132 at the drain position. The contact 228 connects to the top drain electrode 224, which connects to the signal line 250 through the via 251. The via 252 connects the signal line 250 to the contact 226. The contact 226 connects to the bottom drain electrode 214 from the frontside. The contact 226 lands on the bottom drain electrode 214 with the third signal track.

Cell 308 is a stacked FET cell showing a gate section (Gate) taken at section line Gate in FIG. 1. Cell 308 includes a gate electrode 314 for both the bottom FET 110 and the top FET 120. Cell 308 occupies three track pitches and includes three inbound signal lines 350 at the frontside of the cell 308. One signal line 350 connects to a via of gate contact 352 that connects to the gate electrode 314. Gate electrode 314 indicates channels 312 and 322 therein. The cell 308 includes a boundary 142 that can include a cut region 140, which includes a dielectric material to laterally isolate components within the cell 308.

Channels 312 and 322 can be structures provided by nanosheets during fabrication of the gate electrode 314. The channels 312, 322 include semiconductor material that has a gate dielectric (not shown) formed thereon. The gate electrode 314 is formed over the gate dielectric and fills spaces between the channels 312, 322 (transistor channels). This process is known as a High-K Metal Gate (HKMG) process to form gate structures for selectively activating FETs. The gate electrode 314 can include at least one gate conductor. The gate conductor can include any conductive metal including, but not limited to W, Ni, Ti, Mo, Ta, Cu, Pt, Ag, Au, Ru, Ir, Rh, and Re, and alloys that include at least one of these conductive materials. The gate conductor can include one or more layers of conductive materials. In one example, a second conductive material may be formed. When a combination of conductive elements is employed, an optional diffusion barrier material such as TaN or WN may be formed between the conductive materials. The gate electrode 314 can be deposited by CVD, plasma enhanced CVD (PECVD), ALD or other suitable deposition process.

In cell 308, the channels 322 (transistor channels) are smaller than the channels 312 (transistor channels). The metal lines 130 and 132 can be connected to the gate electrode 314; however, in the embodiment shown in FIG. 2, the gate electrode is isolated from the metal lines 130, 132 by the dielectric material 134 in the interdevice region 160. In other embodiments, contact can be made to the metal lines 130, 132 directly or using contacts. The dielectric material 134 can include one or more dielectric layers.

By moving metal lines 130, 132 (power rails) to a central position in the interdevice region 160, a density of signal lines (contacts, metal lines, etc.) above and below the top FET 120 and the bottom FET 110 can be altered. Space can be above and below the top FET 120 and the bottom FET 110 can be better utilized to permit for a reduction in cell height of the cells 108, 208 and 308. In FIG. 2, cell height is reduced to a three track pitch width, which results in a substantial reduction in area across a semiconductor chip.

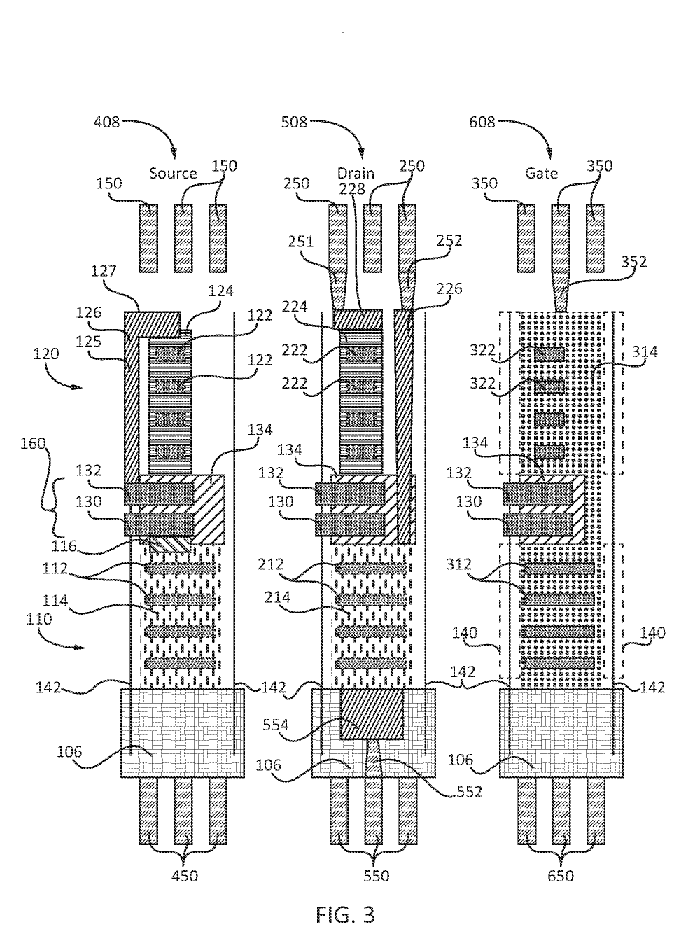

Referring to FIG. 3, cross-sectional views of cells 408, 508 and 608 are shown in accordance with another embodiment. Cells 408, 508 and 608 include six signal lines in a three track cell height. Cell 408 is a stacked FET cell showing for a source section (Source) taken at section line Source in FIG. 1. Cell 408 includes the bottom source electrode 114 for the bottom FET 110 and the top source electrode 124 for the top FET 120. Cell 408 occupies three tracks (pitches) and includes three inbound signals lines 150 at a frontside of the cell 408. However, the cell 408 includes three additional signal lines 450 within the same cell height, but on an opposite side of the cell 408.

In cell 408, the channel positions 112 (transistor channels) are larger than channel positions 122 (transistor channels). It should be understood that in some embodiments, this could be reversed so that the transistor channels of a top FET could be larger than the transistor channels of a bottom FET. The transistor channels for the top or bottom FET can also be a same size.

The bottom source electrode 114 and the top source electrode 124 are vertically separated by the interdevice region 160. The interdevice region 160 can include the dielectric material 134, which is built up in layers during fabrication to permit one or more metal lines 130, 132 (power lines) to be formed therein. In the embodiment shown, two stacked metal lines 130 and 132 are shown disposed within the interdevice region 160. However, one, two, three or more metal lines can be employed. The metal lines 130 and 132 are shown vertically aligned to one another. In other embodiments, the metal lines 130 and 132 can be vertically offset from one another to provide access areas for contacts or vias to land from a frontside or backside of the cell 408.

The metal lines 130 and 132 can be connected to the top source electrode 124 and/or the bottom source electrode 114 or pass between the top source electrode 124 and/or the bottom source electrode 114 without connections, depending on the embodiment. The metal line 130 is connected to a contact 116 to electrically access the bottom source electrode 114. In an embodiment, a similar direct contact (116) can be employed between metal line 132 and the top source electrode 124.

Cell 508 is a stacked FET cell showing the drain section (Drain) taken at section line Drain in FIG. 1. Cell 508 includes the bottom drain electrode 214 for the bottom FET 110 and the top drain electrode 224 for the top FET 120. Cell 508 occupies three tracks (pitches) and includes three inbound signal lines 250 at the frontside of the cell 508. One signal line 250 connects to the via 251 that connects to the contact 228 of the top drain electrode 224. Another signal line 250 connects to the via 252 that connects to the contact 226 of the bottom drain electrode 214. The contact 226 passes through the dielectric material 134. The cell 508 includes three additional signal lines 550, but on an opposite side of the cell 508.

The bottom drain electrode 214 and the top drain electrode 224 are vertically separated by the interdevice region 160. The interdevice region 160 can include the dielectric material 134, which is built up in layers during fabrication to permit one or more metal lines 130, 132 (power lines) to be formed therein. In the embodiment shown, two stacked metal lines 130 and 132 are shown disposed within the interdevice region 160. However, one, two, three or more metal lines can be employed. The metal lines 130 and 132 are shown vertically aligned to one another. In other embodiments, the metal lines 130 and 132 can be vertically offset from one another to provide access areas for contacts or vias to land from the frontside or backside of the cell 508.

The metal lines 130 and 132 can be connected to the top drain electrode 224 and/or the bottom drain electrode 214. In the embodiment shown in FIG. 3, the top drain electrode 224 is not connected to the metal line 130 and the bottom drain electrode 214 is not connected to the metal line 132. Instead, the metal lines pass through the interdevice region 160. In other embodiments, contacts can be made to the metal lines 130, 132 at the drain position. The contact 228 connects to the top drain electrode 224, which connects to the signal line 250 through the via 251. The via 252 connects the signal line 250 to the contact 226. The contact 226 connects to the bottom drain electrode 214 from the frontside. The contact 226 lands on the bottom drain electrode 214 with the third signal track.

The bottom drain electrode 214 is connected to a central signal line 550 by a via 552 and a contact 554. The contact 554 can take advantage of the space provided by the other tracks since no other connections are present from the signal lines 550 and the bottom drain electrode 214. Contacts 226 and 554 to bottom drain electrode 214 can be used separately or together as needed or desired.

Cell 608 is a stacked FET cell showing a gate section (Gate) taken at section line Gate in FIG. 1. Cell 608 includes a gate electrode 314 for both the bottom FET 110 and the top FET 120. Cell 608 occupies three tracks (pitches) and includes three inbound signal lines 350 at the frontside of the cell 608 and three signal lines 650 at the backside of the cell 608. One signal line 350 connects to the via of gate contact 352 that connects to the gate electrode 314. It should be understood that a gate contact can be made from the bottom signal lines 650 instead of or in addition to gate contact 352. In cell 608, channels 312 are larger than channels 322.

The metal lines 130 and 132 can be connected to the gate electrode 314; however, in the embodiment shown in FIG. 3, the gate electrode is isolated from the metal lines 130, 132 by the dielectric material 134 in the interdevice region 160. In other embodiments, contact can be made to the metal lines 130, 132 directly or using contacts.

By moving metal lines 130, 132 (power rails) to a central position in the interdevice region 160, a density of signal lines (contacts, metal lines, etc.) above and below the top FET 120 and the bottom FET 110 can be altered. Space can be above and below the top FET 120 and the bottom FET 110 can be better utilized to permit for a reduction in cell height of the cells 408, 508 and 608. In FIG. 3, cell height is reduced to a three track pitch width, which results in a substantial reduction in area across a semiconductor chip.

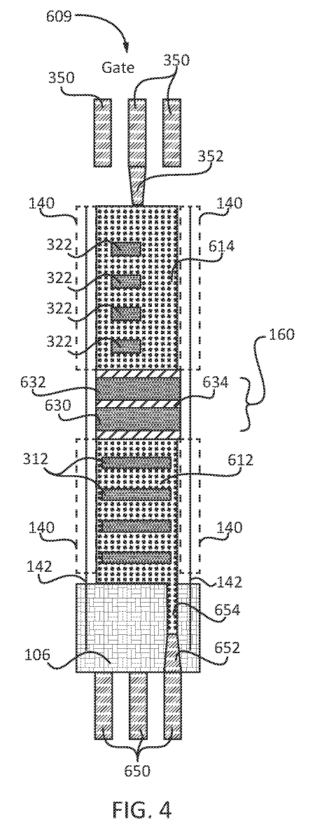

Referring to FIG. 4, in another embodiment, a cell 609 is a stacked FET cell showing a gate section (Gate) taken at section line Gate in FIG. 1. Cell 609 includes a split gate electrode having a gate electrode 612 corresponding to the bottom FET 110, and a gate electrode 614 corresponding to a the top FET 120. Cell 609 occupies three tracks (pitches) and includes three inbound signal lines 350 at the frontside of the cell 609, and occupies three tracks (pitches) and includes three inbound signal lines 650 at the backside of the cell 609. One signal line 350 connects to the gate contact 352 that connects to the gate electrode 614. One signal line 650 connects to a via 652 and a gate contact 654 to electrically access the gate electrode 612.

In cell 609, the channels 312 (transistor channels) are larger than channels 322. It should be understood that in some embodiments, this could be reversed so that the transistor channels of a top FET could be larger than the transistor channels of a bottom FET. The transistor channels for the top or bottom FET can also be a same size.

Metal lines 630 and 632 are encapsulated in the dielectric material 634. The dielectric material 634 can include a same material and processing and dielectric material 134. Similarly. The metal lines 630 and 632 can be formed of a same material and processing as metal lines 130, 132. The metal lines 630 and 632 extend across a width of the cell 609 as does the dielectric material 634. In this way, the gate electrodes 612 and 614 are separated by the interdevice region 160. The power lines or metal lines 630 and 632 can include a positive supply voltage (VDD) and a negative supply voltage (VSS) (or vice versa).

The metal lines 630 and 632 can be connected to the gate electrode 614 or gate electrode 612; however, in the embodiment shown in FIG. 4, the gate electrodes 614, 612 are isolated from the metal lines 130, 132 by the dielectric material 134 in the interdevice region 160. In other embodiments, contact can be made to the metal lines 130, 132 directly or using contacts.

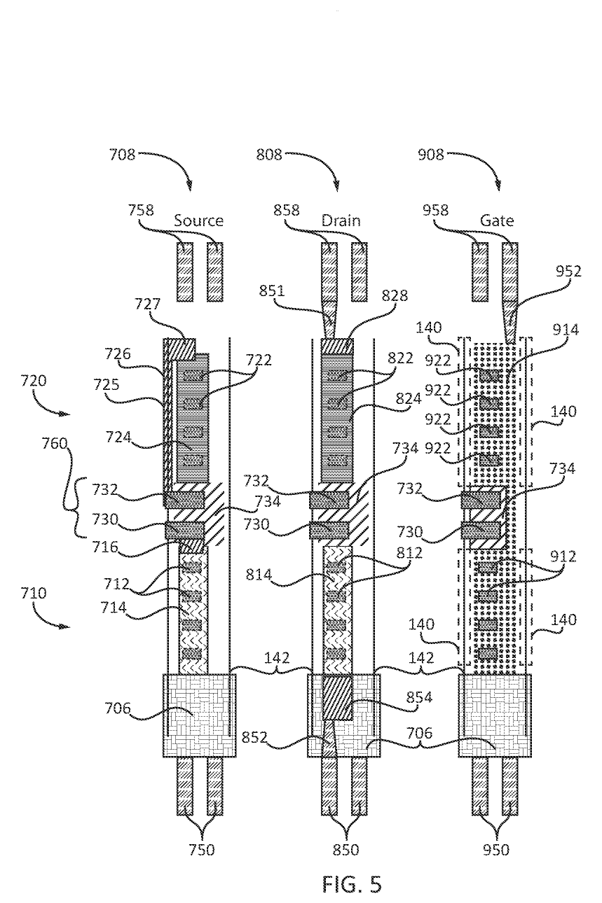

Referring to FIG. 5, cross-sectional views of cells 708, 808 and 908 are shown in accordance with another embodiment. Cells 708, 808 and 908 include four signal lines in a two track pitch cell height. Cell 708 is a stacked FET cell showing a source section (Source) taken at section line Source in FIG. 1. Cell 708 includes a bottom source electrode 714 for a bottom FET 710 and a top source electrode 724 for a top FET 720. Cell 708 occupies two tracks (pitches) as indicated by two signal lines 758 at a frontside of the cell 708. However, the cell 708 includes two additional signal lines 750 within the same two track pitch, but on an opposite side of the cell 708.

In cell 708, the channel positions 712 (transistor channels) are a same size as channel positions 722. The bottom source electrode 714 and the top source electrode 724 are vertically separated by the interdevice region 760. The interdevice region 760 can include a dielectric material 734, which is built up in layers during fabrication to permit one or more metal lines 730, 732 (power lines) to be formed therein. In the embodiment shown, two stacked metal lines 730 and 732 are shown disposed within the interdevice region 760. However, one, two, three or more metal lines can be employed. The metal lines 730 and 732 are shown vertically aligned to one another. In other embodiments, the metal lines 730 and 732 can be vertically offset from one another to provide access areas for contacts or vias to land from a frontside or backside of the cell 708.

The metal lines 730 and 732 can be connected to the top source electrode 724 and/or the bottom source electrode 714 or pass between the top source electrode 724 and/or the bottom source electrode 714 without connections, depending on the embodiment. The metal line 730 is connected to a contact 716 to electrically access the bottom source electrode 714. It should be understood that a number of connection options exist for connecting the metal lines 730 and 732 to S/D electrodes. These can include indirect and/or line of sight connections to one or both of the metal lines 730 and 732 to each of or both of the top S/D electrodes and/or the bottom S/D electrodes. Any combination of connections can be realized in accordance with a desired wiring scheme. The power lines or metal lines 730 and 732 can include a positive supply voltage (VDD) and a negative supply voltage (VSS) (or vice versa).

Cell 808 is a stacked FET cell showing the drain section (Drain) taken at section line Drain in FIG. 1. Cell 808 includes the bottom drain electrode 814 for the bottom FET 710 and the top drain electrode 824 for the top FET 720. Cell 808 occupies two tracks (pitches) and includes two signal lines 858 at the frontside of the cell 808. One signal line 858 connects to a via 851 that connects to a contact 828 of the top drain electrode 824. The cell 808 includes two additional signal lines 850 within the same two tracks, but on an opposite side of the cell 808.

The bottom drain electrode 814 and the top drain electrode 824 are vertically separated by the interdevice region 760. The interdevice region 760 can include the dielectric material 734, which is built up in layers during fabrication to permit one or more metal lines 730, 732 (power lines) to be formed therein. In the embodiment shown, two stacked metal lines 730 and 732 are shown disposed within the interdevice region 760. However, one, two, three or more metal lines can be employed. The metal lines 730 and 732 are shown vertically aligned to one another. In other embodiments, the metal lines 730 and 732 can be vertically offset from one another to provide access areas for contacts or vias to land from the frontside or backside of the cell 808.

The metal lines 730 and 732 can be connected to the top drain electrode 824 and/or the bottom drain electrode 814. In the embodiment shown in FIG. 5, the top drain electrode 824 is not connected to the metal line 730, and the bottom drain electrode 814 is not connected to the metal line 832. Instead, the metal lines 730, 732 pass unconnected through the interdevice region 760. In other embodiments, contact can be made to the metal lines 730, 732 at the drain position. A contact 828 connects to the top drain electrode 824, which connects to the signal line 858 through the via 851. A via 852 connects the signal line 858 to a contact 854. The contact 854 connects to the bottom drain electrode 814 from the backside.

Cell 908 is a stacked FET cell showing a gate section (Gate) taken at section line Gate in FIG. 1. Cell 908 includes a gate electrode 914 for both the bottom FET 710 and the top FET 720. Cell 908 occupies two tracks (pitches) and includes two signal lines 958 at the frontside of the cell 908, and occupies two tracks (pitches) as indicated by two signal lines 950 at the backside of the cell 908. One signal line 958 connects to a gate contact 952 that connects to the gate electrode 914. In cell 908, channels 922 are a same size as channels 912.

The metal lines 730 and 732 can be connected to the gate electrode 914; however, in the embodiment shown in FIG. 5, the gate electrode 914 is isolated from the metal lines 930, 932 by the dielectric material 734 in the interdevice region 760. In other embodiments, contact can be made to the metal lines 730, 732 directly or using contacts.

By moving metal lines 730, 732 (power rails) to a central position in the interdevice region 760, a density of signal lines (contacts, metal lines, etc.) above and below the top FET 720 and the bottom FET 710 can be altered (e.g., increased). Space can be above and below the top FET 720 and the bottom FET 710 can be better utilized to permit for a reduction in cell height of the cells 708, 808 and 908. In FIG. 5, cell height is reduced to a two track pitch width, which results in a substantial reduction in area across a semiconductor chip.

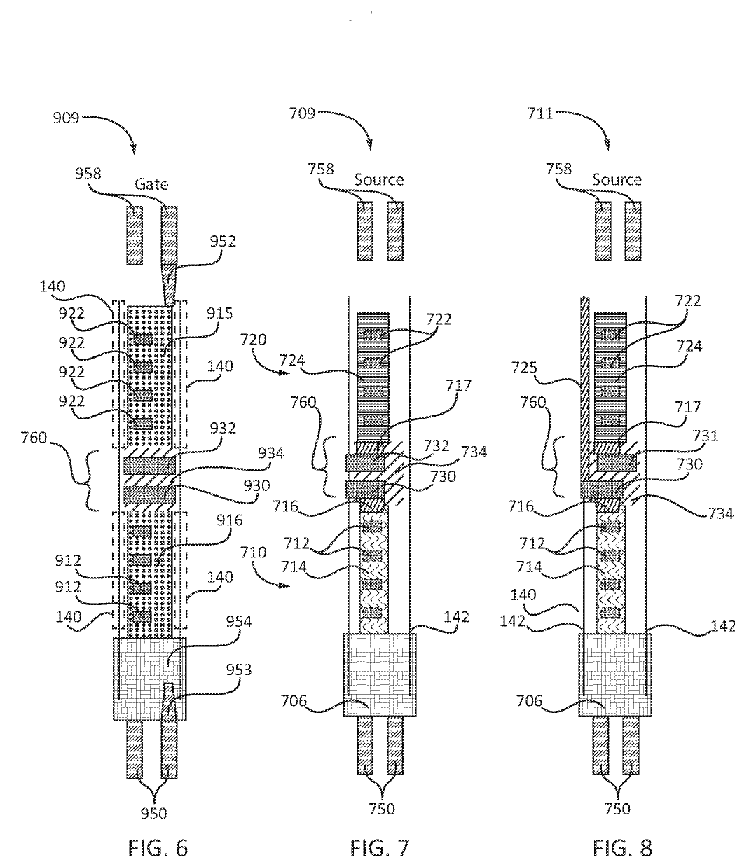

Referring to FIG. 6, in another embodiment, a cell 909 is a stacked FET cell showing a gate section (Gate) taken at section line Gate in FIG. 1. Cell 909 includes a split gate electrode having a gate electrode 916 corresponding to the bottom FET 710, and a gate electrode 915 corresponding to the top FET 720. Cell 909 occupies two tracks (pitches) and include four signal lines (952, 950). One signal line 958 connects to the gate contact 952 that connects to the gate electrode 915. One signal line 950 connects to a via 953 and a gate contact 954 to electrically access the gate electrode 916. In cell 909, channels 922 are a same size as channels 912.

Metal lines 930 and 932 are encapsulated in the dielectric material 934. The dielectric material 934 can include a same material and processing as dielectric material 134. Similarly. The metal lines 930 and 932 can be formed of a same material and processing as metal lines 130, 132. The metal lines 930 and 932 extend across a width of the cell 909 as does the dielectric material 934. In this way, the gate electrodes 915 and 916 are separated by the interdevice region 760.

The metal lines 930 and 932 can be connected to the gate electrode 915 or gate electrode 916; however, in the embodiment shown in FIG. 6, the gate electrodes 915, 916 are isolated from the metal lines 930, 932 by the dielectric material 934 in the interdevice region 760. In other embodiments, contact can be made to the metal lines 930, 932 directly or using contacts.

Referring to FIG. 7, in another embodiment, a cell 709 includes four signal lines in a two track pitch cell height. Cell 709 is a stacked FET cell showing a source section (Source) taken at section line Source in FIG. 1. Cell 709 includes the bottom source electrode 714 for the bottom FET 710 and the top source electrode 724 for the top FET 720. Cell 709 occupies two tracks (pitches) including two signal lines 758 at the frontside of the cell 709. The cell 709 includes two additional signal lines 750 within the same two tracks, but on an opposite side of the cell 709.

In cell 709, the top source electrode 724 includes a two track pitch width, and the bottom source electrode 714 includes a two track pitch width.

The bottom source electrode 714 and the top source electrode 724 are vertically separated by the interdevice region 760. The interdevice region 760 can include a dielectric material 734, which is built up in layers during fabrication to permit one or more metal lines 730, 732 (power lines) to be formed therein. In the embodiment shown, two stacked metal lines 730 and 732 are shown disposed within the interdevice region 760. However, one, two, three or more metal lines can be employed. The metal lines 730 and 732 are shown vertically aligned to one another. In other embodiments, the metal lines 730 and 732 can be vertically offset from one another to provide access areas for contacts or vias to land from a frontside or backside of the cell 709.

In the embodiment shown in FIG. 7, the metal line 732 is connected to the top source electrode 724 by a contact 717, and the metal line 730 is connected to the bottom source electrode 714 by the contact 716. It should be understood that the configuration depicted in FIG. 7 can not only be applied to the source cells but can also be applied to the drain cells and/or the gate cells. Said differently, contacts can be employed between the metal lines and respective tops and/or bottoms of source, drain or gate electrodes for one or both of the stacked FETs.

In addition, contacts (connections) can be made from signal lines to an adjacent source, drain or gate electrodes or to a distant source, drain or gate electrodes. Multiple contacts can also be made to each of the source, drain or gate electrodes. For example, the electrode (source, drain or gate electrode) can be contacted from a frontside, a backside and/or an interdevice region. It should also be understood that the multiple configuration as described with respect to two track cells are applicable to three tracks cells and vice versa. For example, the electrode (source, drain or gate electrode) can be contacted from a frontside, a backside and/or an interdevice region in a three track cell or a two track cell.

Referring to FIG. 8, in another embodiment, a cell 711 includes four signal lines in two tracks. Cell 711 is a stacked FET cell showing a source section (Source) taken at section line Source in FIG. 1. Cell 711 includes the bottom source electrode 714 for the bottom FET 710 and the top source electrode 724 for the top FET 720. Cell 711 occupies two tracks (pitches) as indicated by two signal lines 758 at the frontside of the cell 711. The cell 711 includes two additional signal lines 750 within the same two tracks, but on an opposite side of the cell 711.

In cell 711, channels associated with the top source electrode 724 as indicated by channel positions 722 are a same size as channels associated with the bottom source electrode 714 as indicated by channel positions 712.

The bottom source electrode 714 and the top source electrode 724 are vertically separated by the interdevice region 760. The interdevice region 760 can include a dielectric material 734, which is built up in layers during fabrication to permit one or more metal lines 730, 731 (power lines) to be formed therein. In the embodiment shown, two stacked metal lines 730 and 731 are shown disposed within the interdevice region 760. However, one, two, three or more metal lines can be employed. The metal lines 730 and 731 are shown misaligned relative to one another (e.g., vertically offset from one another) to provide access areas for a contact 723 to land from the frontside of the cell 711. The power lines or metal lines 730 and 731 can include a positive supply voltage (VDD) and a negative supply voltage (VSS) (or vice versa).

In the embodiment shown in FIG. 8, the metal line 731 is connected to the top source electrode 724 by the contact 717, and the metal line 731 is connected to the top source electrode 724 at a top by L-shaped contact 726. The metal line 730 is connected to the bottom source electrode 714 by the contact 716. The contact 725 can also connect the metal line 730 to topside metal structures such as, e.g., BEOL structures. In an embodiment, the contact 725 could also connect with another electrode (e.g., another top source electrode 724 or even the same top source electrode 724).

It should be understood that the configuration depicted in FIG. 8 can not only be applied to the source cells but can also be applied to the drain cells and/or the gate cells. Said differently, contacts can be employed between the metal lines and respective tops and/or bottoms of source, drain or gate electrodes for one or both of the stacked FETs.

In addition, contacts (connections) can be made from signal lines to an adjacent source, drain or gate electrodes or to a distant source, drain or gate electrodes. Multiple contacts can also be made to each of the source, drain or gate electrodes. For example, the electrode (source, drain or gate electrode) can be contacted from a frontside, a backside and/or an interdevice region. It should also be understood that the multiple configuration as described with respect to two track cells are applicable to three track cells and vice versa. For example, the electrode (source, drain or gate electrode) can be contacted from a frontside, a backside and/or an interdevice region in a three track cell or a two track cell.

In other embodiments, while the FIGs. depict two metal lines (e.g., metal lines 130, 132, etc.) in the interdevice regions (e.g., interdevice region 160), one metal line or more than two metal lines can be implemented within a device. In still other embodiments, more than three signal lines (e.g., three signal lines 150) can be employed in Source, Drain or Gate cells. In addition, the signal lines do not need to be evenly spaced relative to one another and instead can have different fractional spacings therebetween for a given cell. Signal lines on a top of a cell do not have to be vertically aligned with signal lines on a bottom of the cell. For example, the three signal lines 150 for cell 408 need not be vertically aligned with three signal lines 450. Instead, an offset may be present for all the signal lines or less than all of the signal lines relative to one another or a top set of signal lines relative to the bottom set of signal lines.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor- or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a stacked transistor structure having field effect transistors on two vertically stacked levels;
an interdevice region disposed between the two vertically stacked levels;
a first power line disposed within the interdevice region; and
a second power line disposed within the interdevice region and vertically spaced about from the first power line.

2. The semiconductor device as recited in claim 1, wherein the first power line connects to a source/drain electrode of a field effect transistor by a line-of-sight contact.

3. The semiconductor device as recited in claim 1, wherein the first power line connects to source/drain electrodes on the two vertically stacked levels.

4. The semiconductor device as recited in claim 1, wherein the first power line is encapsulated by dielectric material and the dielectric material separates a gate into corresponding gate conductors for the two vertically stacked levels.

5. The semiconductor device as recited in claim 1, wherein the second power line is vertically aligned with the first power line.

6. The semiconductor device as recited in claim 1, wherein the second power line is vertically misaligned from the first power line.

7. The semiconductor device as recited in claim 1, wherein the first power line connects to a field effect transistor on a first level and the second power line connects to a field effect transistor on a second level.

8. The semiconductor device as recited in claim 1, wherein the first power line includes a positive supply voltage (VDD) and the second power line includes a negative supply voltage (VSS).

9. A semiconductor device, comprising:
a stacked transistor structure having field effect transistors on two vertically stacked levels and disposed within a three track pitch width;
an interdevice region disposed between the two vertically stacked levels within the three track pitch width; and
a first power line disposed within the interdevice region.

10. The semiconductor device as recited in claim 9, wherein the first power line connects to a source/drain electrode of a field effect transistor by a line-of-sight contact.

11. The semiconductor device as recited in claim 9, wherein the first power line connects to source/drain electrodes on the two vertically stacked levels.

12. The semiconductor device as recited in claim 9, wherein the first power line is encapsulated by dielectric material and the dielectric material separates a gate conductor between the two vertically stacked levels.

13. The semiconductor device as recited in claim 9, further comprising a second power line disposed within the interdevice region, wherein the second power line is vertically aligned with the first power line.

14. The semiconductor device as recited in claim 9, further comprising a second power line disposed within the interdevice region, wherein the second power line is vertically misaligned from the first power line.

15. The semiconductor device as recited in claim 9, wherein the stacked transistor structure includes six signal lines within the three track pitch width.

16. The semiconductor device as recited in claim 9, wherein the stacked transistor structure is disposed within a two track pitch width.

17. The semiconductor device as recited in claim 16, wherein the stacked transistor structure includes four signal lines within the two track pitch width.

18. A semiconductor device, comprising:
a stacked transistor structure having field effect transistors on two vertically stacked levels and disposed within a three track pitch width;
an interdevice region disposed between the two vertically stacked levels within the three track pitch width;
a first power line disposed within the interdevice region;
a second power line disposed within the interdevice region and vertically spaced from the first power line; and
a dielectric material in the interdevice region encapsulates the first power line and the second power line.

19. The semiconductor device as recited in claim 18, wherein the interdevice region separates a gate conductor between the two vertically stacked levels.

20. The semiconductor device as recited in claim 18, wherein the stacked transistor structure is disposed within a two track pitch width.
